(19) United States
(12) Patent Application Publication
(10) Pub. No.: US 2025/0089167 A1
(43) Pub. Date: Mar. 13, 2025

(54) WIRING SUBSTRATE

(71) Applicant: IBIDEN CO., LTD., Ogaki (JP)

(72) Inventors: Shunsuke SAKAI, Ogaki (JP); Yoshio MIZUTANI, Ogaki (JP)

(73) Assignee: IBIDEN CO., LTD., Ogaki (JP)

(21) Appl. No.: 18/882,148

(22) Filed: Sep. 11, 2024

(30) Foreign Application Priority Data
Sep. 12, 2023 (JP) 2023-147846

(51) Int. Cl. H05K 1/11; H05K 1/18; H05K 3/00; H05K 3/42

(52) U.S. Cl. CPC H05K 1/115; H05K 1/181; H05K 3/0047; H05K 3/42; H05K 2201/09545; H05K 2201/0959; H05K 2201/09636; H05K 2203/143

(57) ABSTRACT

A wiring substrate includes an insulating layer having through holes, a first conductor layer, a second conductor layer, interlayer conductors formed in the through holes. The interlayer conductors are connecting the first and second conductor layers and include first interlayer conductors formed in first region of the insulating layer and second interlayer conductors formed in second region of the insulating layer at density higher than density of the first interlayer conductors formed in the first region. A thickness of each first interlayer conductor is larger than a thickness of each second interlayer conductor. The insulating layer is formed such that the through holes includes first through holes having the first interlayer conductors formed therein and second through holes having the second interlayer conductors formed therein and that an inner diameter of each of the first through holes is larger than an inner diameter of each of the second through holes.

### CROSS-REFERENCE TO RELATED APPLICATIONS

The present application is based upon and claims the benefit of priority to Japanese Patent Application No. 2023-147846, filed Sep. 12, 2023, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2023-20516 describes a method for manufacturing a printed wiring board having a high-density region and a low-density region of through holes formed in an insulating layer. The entire contents of this publication are incorporated herein by reference.

### SUMMARY OF THE INVENTION

According to one aspect of the present invention, a wiring substrate includes an insulating layer having through holes, a first conductor layer formed on a first surface of the insulating layer, a second conductor layer formed on a second surface of the insulating layer on the opposite side with respect to the first surface of the insulating layer, interlayer conductors formed in the through holes of the insulating layer respectively such that the interlayer conductors are connecting the first and second conductor layers and include first interlayer conductors formed in a first region of the insulating layer and second interlayer conductors formed in a second region of the insulating layer at a density that is higher than a density of the first interlayer conductors formed in the first region. The interlayer conductors are formed such that a thickness of each of the first interlayer conductors is larger than a thickness of each of the second interlayer conductors, and the insulating layer is formed such that the through holes includes first through holes having the first interlayer conductors formed therein and second through holes having the second interlayer conductors formed therein and that an inner diameter of each of the first through holes is larger than an inner diameter of each of the second through holes.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is a plan view of the wiring substrate of FIG. 1;

FIG. 3A is an enlarged view of a portion (IIIA) of FIG. 1;

FIG. 3B is an enlarged view of a portion (IIIB) of FIG. 1;

FIG. 4A is a cross-sectional view illustrating an example of a manufacturing process of a wiring substrate according to an embodiment of the present invention;

FIG. 4B is a cross-sectional view illustrating an example of a manufacturing process of a wiring substrate according to an embodiment of the present invention;

FIG. 4C is a cross-sectional view illustrating an example of a manufacturing process of a wiring substrate according to an embodiment of the present invention;

FIG. 4D is a cross-sectional view illustrating an example of a manufacturing process of a wiring substrate according to an embodiment of the present invention;

FIG. 4E is a cross-sectional view illustrating an example of a manufacturing process of a wiring substrate according to an embodiment of the present invention;

FIG. 4F is a cross-sectional view illustrating an example of a manufacturing process of a wiring substrate according to an embodiment of the present invention;

FIG. 4G is a cross-sectional view illustrating an example of a manufacturing process of a wiring substrate according to an embodiment of the present invention; and

FIG. 4H is a cross-sectional view illustrating an example of a manufacturing process of a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

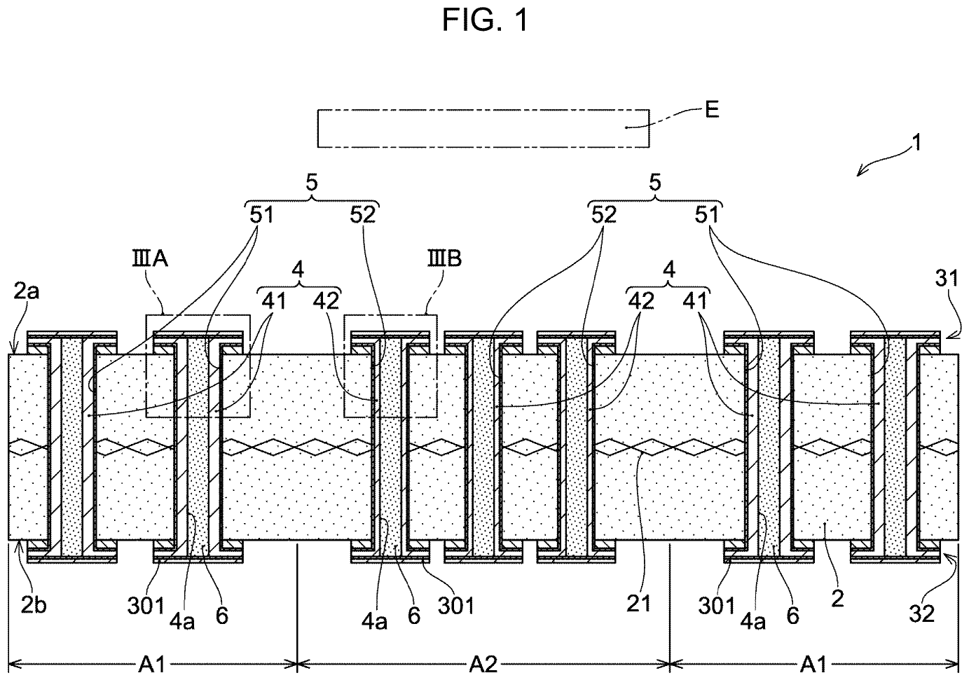

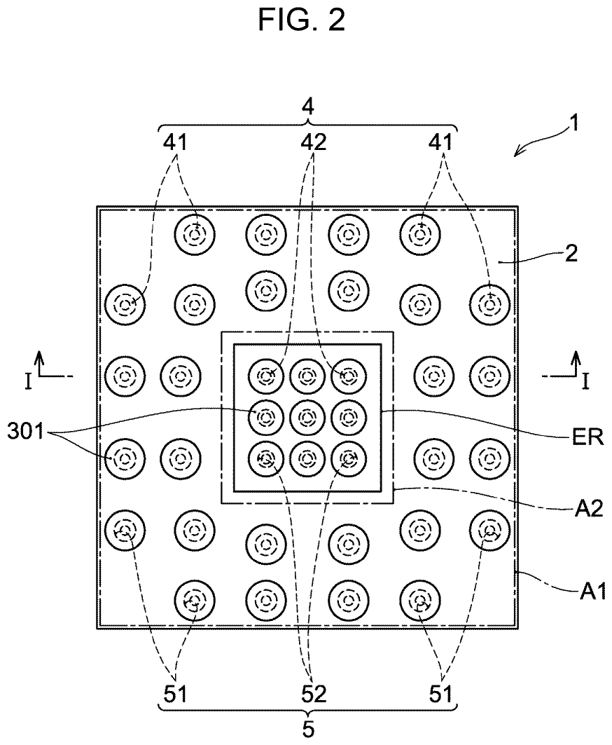

A wiring substrate according to an embodiment of the present invention is described with reference to the drawings. FIG. 1 illustrates a cross-sectional view of a wiring substrate 1, which is an example of the wiring substrate of the present embodiment. FIG. 2 illustrates a plan view of the wiring substrate 1 of FIG. 1. FIG. 1 is a cross-sectional view of the wiring substrate 1 along an I-I line illustrated in FIG. 2. The wiring substrate 1 is merely an example of the wiring substrate of the embodiment. For example, the number of conductor layers and the number of insulating layers included in the wiring substrate of the embodiment are not limited to the number of conductor layers and the number of insulating layers included in the wiring substrate 1 of FIG. 1. That is, the wiring substrate of the embodiment can include any number of insulating layers and conductor layers in addition to the insulating layers and conductor layers of the wiring substrate 1. In the drawings to be referenced in the following description, in order to facilitate understanding of an embodiment to be disclosed, a specific portion may be depicted in an enlarged manner and it may be possible that structural elements are not depicted in precise proportions in terms of size or length relative to each other.

As illustrated in FIG. 1, the wiring substrate 1 includes: an insulating layer 2; two conductor layers (conductor layer 31 and conductor layer 32) facing each other via the insulating layer 2; and multiple interlayer conductors 4 that connect the conductor layer 31 and the conductor layer 32. The insulating layer 2 has a first surface (2a) and a second surface (2b) as two surfaces that are orthogonal to a thickness direction of the insulating layer 2 and oppose each other. The conductor layer 31 (first conductor layer) is formed on the first surface (2a), and the conductor layer 32 (second conductor layer) is formed on the second surface (2b). The insulating layer 2 further has multiple through holes 5 penetrating between the first surface (2a) and the second surface (2b). The multiple interlayer conductors 4 are respectively formed in the multiple through holes 5. The multiple through holes 5 respectively contain the multiple interlayer conductors 4. The multiple interlayer conductors 4 are respectively formed in tubular shapes along inner walls of the insulating layer 2 surrounding the multiple through holes 5. That is, the interlayer conductors 4 each have a partially film-like structure and, as a whole, a tubular structure with a hollow part (4a).

The multiple interlayer conductors 4 each penetrate the insulating layer 2 and connect the conductor layer 31 and the conductor layer 32. The interlayer conductors 4 can be so-called through-hole conductors. The interlayer conductors 4 are also referred to as via conductors. However, the interlayer conductors 4 are not conductors connecting a conductor layer covered by the insulating layer 2 to any other conductor layer, but are conductors connecting the conductor layers that are respectively directly formed on the two surfaces of the insulating layer 2 that intersect the thickness direction.

The hollow part (4a) of each of the multiple interlayer conductors 4 is filled with a filling body 6. The filling body 6 is formed of, for example, an insulating thermosetting resin such as an epoxy resin or a phenol resin. The filling material 6 may be formed of a conductive resin containing conductive particles and an epoxy resin. However, the materials forming the filling body 6 are not limited to a thermosetting resin and a conductive resin. The filling body 6 can be formed of any resin.

A component (E) is mounted on the wiring substrate 1 in the example of FIG. 1. The component (E) can be, for example, any semiconductor integrated circuit device such as a microcontroller or a memory, as well as a discrete semiconductor element, or a passive element such as a resistor array.

The wiring substrate 1 of FIG. 1 includes only the insulating layer 2, the conductor layer 31, the conductor layer 32, and the interlayer conductors 4. However, as described above, the wiring substrate of the embodiment may further include one or more pairs of insulating layers and conductor layers on each of the first surface (2a) side and the second surface (2b) side of the insulating layer 2. In this case, the insulating layer 2 and the conductor layers (31, 32) may be formed as a core substrate of the wiring substrate of the embodiment and function as a core substrate. In this case, the multiple interlayer conductors 4 can function as through-hole conductors that penetrate the insulating layer of the core substrate and connect the conductor layers on both sides of the insulating layer.

As illustrated in FIGS. 1 and 2, the wiring substrate 1 has a first region (A1) and a second region (A2) in each of which some of the multiple interlayer conductors 4 are formed. The first region (A1) and the second region (A2) are separate regions. The first region (A1) and the second region (A2) are regions where arrangement densities of the interlayer conductors 4 in a plan view are different from each other. The term “plan view” means viewing an object along the thickness direction of the wiring substrate of the embodiment. In the second region (A2), some of the multiple interlayer conductors 4 (second interlayer conductors 42) are formed at a density than an arrangement density of some of the multiple interlayer conductors 4 (first interlayer conductors 41) formed in the first region (A1).

That is, the multiple interlayer conductors 4 include the first interlayer conductors 41 formed in the first region (A1) and the second interlayer conductors 42 formed in the second region (A2). And, the second interlayer conductors 42 are formed in the second region (A2) at a density higher than that of the first interlayer conductors 41 in the first region (A1). Therefore, the multiple through holes 5 also include first through holes 51 formed in the first region (A1) and second through holes 52 formed in the second region (A2) at a density higher than that of the first through holes 51 in the first region (A1). The first interlayer conductors 41 are formed in the first through holes 51, and the second interlayer conductors 42 are formed in the second through holes 52.

As illustrated in FIG. 2, in the example of FIGS. 1 and 2, the second region (A2) occupies a center part of the wiring substrate 1 in a plan view. And, the first region (A1) is provided on an outer side of the second region (A2) in a planar view. The first region (A1) occupies a region on an outer side of the second region (A2) and surrounds the second region (A2). As illustrated in FIG. 2, the wiring substrate 1 has a component mounting region (ER), which is a region where the component (E) illustrated in FIG. 1 is positioned. The component mounting region (ER) may be a region that is covered by the component (E) when the component (E) is mounted on the wiring substrate 1. In the wiring substrate 1, the second region (A2) is provided directly below the component mounting region (ER). Further, the second region (A2) substantially entirely overlaps with the component mounting region (ER) in a plan view. On the other hand, the first region (A1) surrounds the component mounting region (ER) in a plan view.

In the wiring substrate 1 in which the second region (A2) is provided at the center part where some of the multiple interlayer conductors 4 are formed at a higher density than in the first region (A1), high heat dissipation characteristics from an electronic component, such as the component (E), which is likely to be positioned in the center part, may be achieved. Further, wirings can be respectively drawn out from a large number of terminals of an electronic component such as the component (E). However, positions, sizes, and shapes of the first region (A1) and the second region (A2) in the wiring substrate 1 in a plan view are not limited to those in the example of FIGS. 1 and 2. The first region (A1) and the second region (A2) can each have any size and shape at any position in the wiring substrate 1 in a plan view.

The density of the first through holes 51 in the first region (A1) can be 0.6 holes/mm² or more and 1.2 holes/mm² or less. When the through holes 51 are formed at a density in this range, it may be possible that wirings formed at a moderately fine pitch can be easily formed. On the other hand, the density of the second through holes 52 in the second region (A2) can be 6 holes/mm² or more and 10 holes/mm² or less. When the second through holes 52 are formed at a density in this range, the high heat dissipation performance as described above can be achieved and a large number of wirings can be drawn out. On the other hand, it may be possible that the second through holes 52 or the second interlayer conductors 42 can be formed without using highly sophisticated methods.

The insulating layer 2 is formed, for example, using an insulating resin. Examples of the insulating resin forming the insulating layer 2 include thermosetting resins such as an epoxy resin, a bismaleimide triazine resin (BT resin), and a phenol resin. However, the material of the insulating layer 2 is not limited to these exemplified thermosetting resins. For example, the insulating layer 2 can be formed using any material, such as a thermoplastic resin, that allows the insulating layer 2 to have suitable insulation performance and rigidity. In the example of FIG. 1, the insulating layer 2 contains, for example, a reinforcing material (core material) 21 formed of a glass fiber, an aramid fiber, or the like. The insulating layer 2 may further contain an inorganic filler (not illustrated) formed of silica, alumina, or the like.

In the example of FIGS. 1 and 2, the conductor layer 31 and the conductor layer 32 each include only conductor pads 301 that are connected to the interlayer conductors 4. The conductor pads 301 can be so-called through-hole pads when the interlayer conductors 4 are through-hole conductors as described above. In the wiring substrate of the embodiment, the conductor layers (31, 32) can each include any conductor patterns.

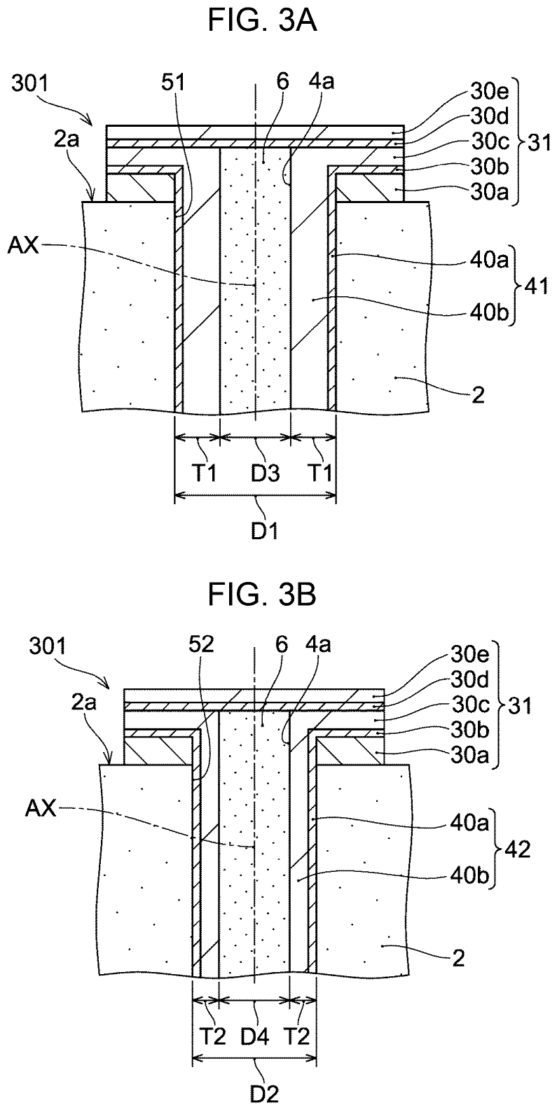

The conductor layer 31, the conductor layer 32, and the interlayer conductors 4 are each formed, for example, using any metal such as copper or nickel. The conductor layer 31, the conductor layer 32, and the interlayer conductors 4 are each formed of metal films formed by electroless plating, electrolytic plating, sputtering, or the like. The conductor layers (31, 32) can each further include a metal foil such as a copper foil or a nickel foil as a structural element. That is, as clearly illustrated in FIGS. 3A and 3B, the conductor layer 31, the conductor layer 32, and the interlayer conductors 4 can each have a multi-layer structure including two or more metal films.

FIG. 3A is an enlarged view of a part (IIIA) of FIG. 1, that is, an enlarged view of a first through hole 51 and a first interlayer conductor 41, as well as a conductor pad 301, near the first surface (2a) of the insulating layer 2. FIG. 3B is an enlarged view of a part (IIIB) of FIG. 1, that is, an enlarged view of a second through hole 52 and a second interlayer conductor 42, as well as a conductor pad 301, near the first surface (2a) of the insulating layer 2. As illustrated in FIGS. 3A and 3B, in the wiring substrate 1 of the example of FIG. 1, the conductor pad 301, that is, the conductor layer 31, has a five-layer structure. Specifically, the conductor layer 31 is composed of a first layer (30a), a second layer (30b), a third layer (30c), a fourth layer (30d), and a fifth layer (30e), which are sequentially laminated on the first surface (2a) of the insulating layer 2. Although not illustrated in FIGS. 3A and 3B, the conductor layer 32 has the same structure as the conductor layer 31 on the second surface (2b) of the insulating layer 2 (see FIG. 1).

The first layer (30a) can be, for example, a metal foil layer formed of a copper foil, a nickel foil, or the like. The second layer (30b) and the fourth layer (30d) can be, for example, metal film layers each formed of an electroless plating film or a sputtering film. The third layer (30c) and the fifth layer (30e) may be metal film layers each formed of an electrolytic plating film. In the wiring substrate of the embodiment, the conductor layers (31, 32) do not necessarily have the five-layer structure illustrated in FIGS. 3A and 3B. For example, it is also possible that the conductor layers (31, 32) do not include the first layer (30a), which can be a metal foil layer. Further, it is also possible that the conductor layers (31, 32) do not include the fourth layer (30d) and fifth layer (30e).

On the other hand, the first interlayer conductor 41 and the second interlayer conductor 42 each include a lower-layer film (40a) in contact with a wall surface of the insulating layer 2 surrounding the first through hole 51 or the second through hole 52, and an upper-layer film (40b) formed on the lower-layer film (40a). The lower-layer film (40a) can be, for example, a metal film formed of an electroless plating film or a sputtering film, and the upper-layer film (40b) can be a metal film formed of an electrolytic plating film. The lower-layer film (40a) is integrally formed with the second layer (30b) of the conductor layer 31 and is continuous with the second layer (30b). The upper-layer film (40b) is integrally formed with the third layer (30c) of the conductor layer 31 and is continuous with the third layer (30c). That is, the metal film forming the lower-layer film (40a) is formed not only in the first through hole 51 or the second through hole 52 but also on the first layer (30a) of the conductor layer 31. Similarly, the metal film forming the upper-layer film (40b) is formed not only in the first through hole 51 or the second through hole 52, but also on the second layer (30b) of the conductor layer 31.

In the wiring substrate of the embodiment, a thickness (T1) of the first interlayer conductor 41 is larger than a thickness (T2) of the second interlayer conductor 42. Specifically, a thickness of the upper-layer film (40b) constituting the first interlayer conductor 41 is greater than a thickness of the upper-layer film (40b) constituting the second interlayer conductor 42. In the wiring substrate 1, a conductor pattern of the conductor layer 31 and a conductor pattern of the conductor layer 32 (hereinafter also referred to as the “front and back conductor patterns”) may be connected by one or more of the multiple interlayer conductors 4 (see FIG. 1). In this case, electrical resistance between the front and back conductor patterns is, in principle, inversely proportional to the number of the interlayer conductors 4, that is, the first interlayer conductors 41 or the second interlayer conductors 42, that connect the front and back conductor patterns.

In this regard, as described above, the first interlayer conductors 41 are formed at a lower density in the first region (A1) (see FIG. 2) compared to the second interlayer conductors 42. Therefore, there is likely to be a difference between the number of the first interlayer conductors 41 connecting the front and back conductor patterns and the number of the second interlayer conductors 42 connecting the front and back conductor patterns. As a result, a difference may occur between the electrical resistance between the front and back conductor patterns in the second region (A2) and the electrical resistance between the front and back conductor patterns in the first region (A1). That is, the electrical resistance between the front and back conductor patterns may vary between the regions of the wiring substrate 1 in a plan view.

However, in the present embodiment, as described above, the thickness (T1) of each of the first interlayer conductors 41 is larger than the thickness (T2) of each of the second interlayer conductors 42. Therefore, each of the first interlayer conductors 41 can have a lower electrical resistance than each of the second interlayer conductors 42. Therefore, it is thought that the difference between the electrical resistance between the front and back conductor patterns in the first region (A1) and the electrical resistance between the front and back conductor patterns in the second region (A2), which is due to the difference in arrangement density between the first interlayer conductors 41 and the second interlayer conductors 42, is reduced. Therefore, in the wiring substrate 1, it may be possible that desired electrical characteristics can be easily obtained.

The thickness (T1) of each of the first interlayer conductors 41 and the thickness (T2) of each of the second interlayer conductors 42 are each a distance between an outer wall and an inner wall of each of the interlayer conductors in a radial direction from a central axis (AX) of each of the first through holes 51 or the second through holes 52. When the thickness of each of the interlayer conductors is not constant in a circumferential direction with respect to the central axis (AX), an intermediate thickness between a maximum thickness and a minimum thickness is the thickness of each of the interlayer conductors. Similarly, when the thickness of each of the interlayer conductors is not constant in a direction along the central axis (AX), an intermediate thickness between a maximum thickness and a minimum thickness is the thickness of each of the interlayer conductors.

As an example, the difference between the thickness (T1) of each of the first interlayer conductors 41 and the thickness (T2) of each of the second interlayer conductors 42 is 15% or more and 40% or less of the thickness (T1) of each of the first interlayer conductors 41. It may be possible that the first and second interlayer conductors (41, 42) having such a difference in thickness can be easily formed when the first region (A1) and the second region (A2) have the arrangement densities of the through holes as exemplified above. Further, as described above, it is thought that the difference in the electrical resistance between the front and back conductor patterns between the first region (A1) and the second region (A2) is sufficiently reduced.

Then, in the wiring substrate of the embodiment, as illustrated in FIGS. 3A and 3B, an inner diameter (D1) of the first through hole 51 is larger than an inner diameter (D2) of the second through hole 52. That is, an outer diameter of the first interlayer conductor 41 is larger than an outer diameter of the second interlayer conductor 42. For convenience, the terms “inner diameter” and “outer diameter” are used. However, a shape of a cross section (cross section orthogonal to the central axis (AX)) of each of the first and second through holes (51, 52) and the first and second interlayer conductors (41, 42) is not limited to a circular or elliptical shape. The “inner diameter” of each of the first and second through holes (51, 52) and the “outer diameter” of each of the first and second interlayer conductors (41, 42) are each a longest distance between any two points on an outer perimeter of a cross section orthogonal to the central axis (AX).

As illustrated in FIG. 1, the first through hole 51 and the second through hole 52 exemplified in FIGS. 3A and 3B each have a substantially constant inner diameter over an entire length from the first surface (2a) to the second surface (2b) of the insulating layer 2. The first and second interlayer conductors (41, 42) also each have a substantially constant outer diameter over the entire length from the first surface (2a) to the second surface (2b). However, the inner diameter of each of the through holes may vary slightly in the direction along the central axis (AX). When the inner diameter of each of the through holes is not constant along the direction of the central axis (AX), the inner diameter of each of the through holes is an intermediate length between a maximum inner diameter and a minimum inner diameter.

In the wiring substrate of the embodiment, as described above, not only is the thickness (T1) of each of the first interlayer conductors 41 larger than the thickness (T2) of each of the second interlayer conductors 42, but the inner diameter (D1) of each of the first through holes 51 is also larger than the inner diameter (D2) of each of the second through holes 52. Therefore, a difference between an inner diameter (D3) of each of the first interlayer conductors 41 and an inner diameter (D4) of each of the second interlayer conductors 42 does not become as large as would be expected from the difference between the thickness (T1) of each of the first interlayer conductors 41 and the thickness (T2) of each of the second interlayer conductors 42. For example, the difference between the inner diameter (D3) and the inner diameter (D4) is smaller than a difference between twice the thickness (T1) and twice the thickness (T2).

Therefore, both the hollow parts (4a) in the first region (A1) and the hollow parts (4a) in the second region (A2) are likely to be properly filled with the filling bodies 6. For example, it may be possible that, with a single filling process under selected conditions, all the hollow parts (4a) in both the first region (A1) and the second region (A2) can be filled with the filling body 6 without leaving any unfilled parts such as voids. Therefore, in the wiring substrate of the embodiment, it is thought that bulging is unlikely to occur, and further, cracking in the interlayer conductors or delamination between the insulating layer 2 and each of the interlayer conductors is also unlikely to occur. That is, it is thought that good quality can be obtained in the wiring substrate of the embodiment.

As an example, the inner diameter (D3) of each of the first interlayer conductors 41 may be substantially the same as the inner diameter (D4) of each of the second interlayer conductors 42. That is, the difference between the inner diameter (D1) of each of the first through holes 51 and the inner diameter (D2) of each of the second through holes 52 may be substantially twice the difference between the thickness (T1) of each of the first interlayer conductors 41 and the thickness (T2) of each of the second interlayer conductors 42. In this case, it is thought that the hollow parts (4a) in both the first region (A1) and the second region (A2) can be more reliably filled with the filling material 6 without leaving any voids or the like, and therefore high quality can be more reliably obtained. The term “substantially the same” between the inner diameter (D3) and the inner diameter (D4) means that an absolute value of the difference between the inner diameter (D3) and the inner diameter (D4) is 5% or less relative to the inner diameter (D1) of each of the first through holes 51. Further, the term “substantially twice” includes a range of 95% or more and 105% or less of exactly twice.

As an example, the inner diameter (D1) of each of the first through holes 51 can be 160 μm or more and 220 μm or less, and the inner diameter (D2) of each of the second through holes 52 can be 150 μm or more and 200 μm or less. It is thought that when through holes each have such an inner diameter, the hollow parts (4a) in both the first region (A1) and the second region (A2) can be more reliably and sufficiently filled with the filling material 6, and therefore, high quality can be achieved for the wiring substrate.

In the wiring substrate of the embodiment, the insulating layer 2 may have a thickness of, for example, 1.0 mm or more and 2.0 mm or less. It is thought that, in the wiring substrate of the present embodiment having the first through holes 51 in the first region (A1) that each have an inner diameter larger than that of each of the second through holes 52 in the second region (A2), the hollow parts (4a) in the regions can be sufficiently filled with the filling material 6 even when the insulating layer 2 has a thickness of 1.0 mm or more. Further, it is thought that when the thickness of the insulating layer 2 is 2.0 mm or less, all the hollow parts (4a) can be more reliably and sufficiently filled with the filling material 6 without leaving any unfilled parts.

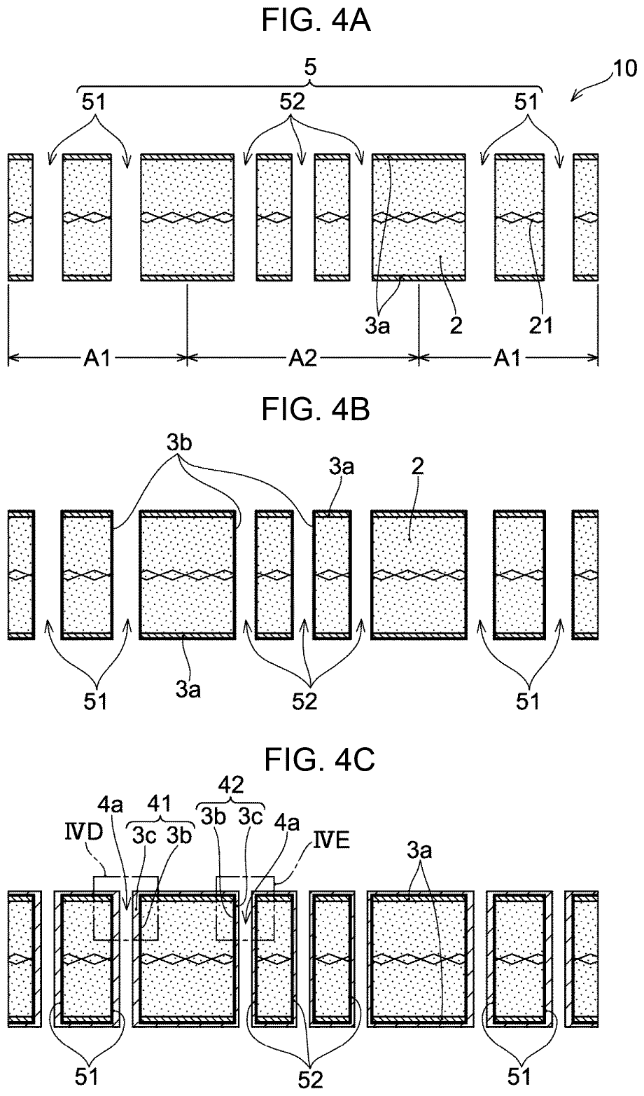

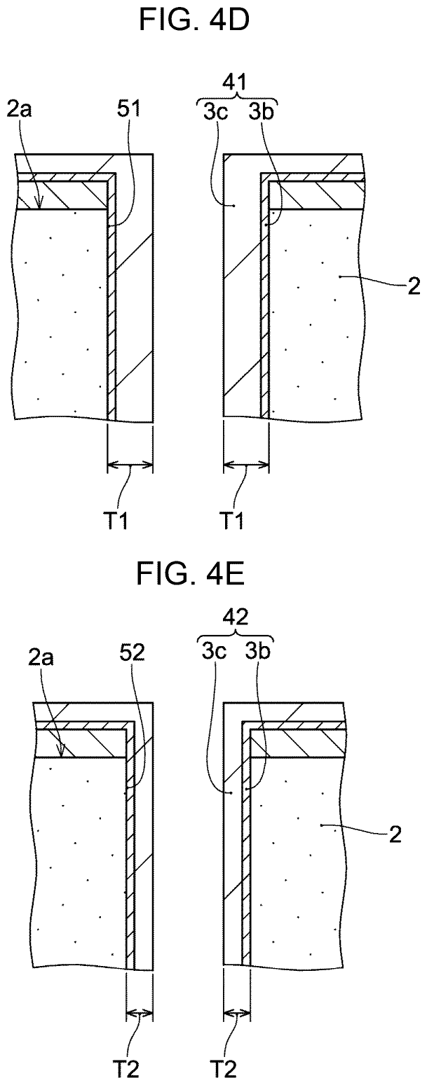

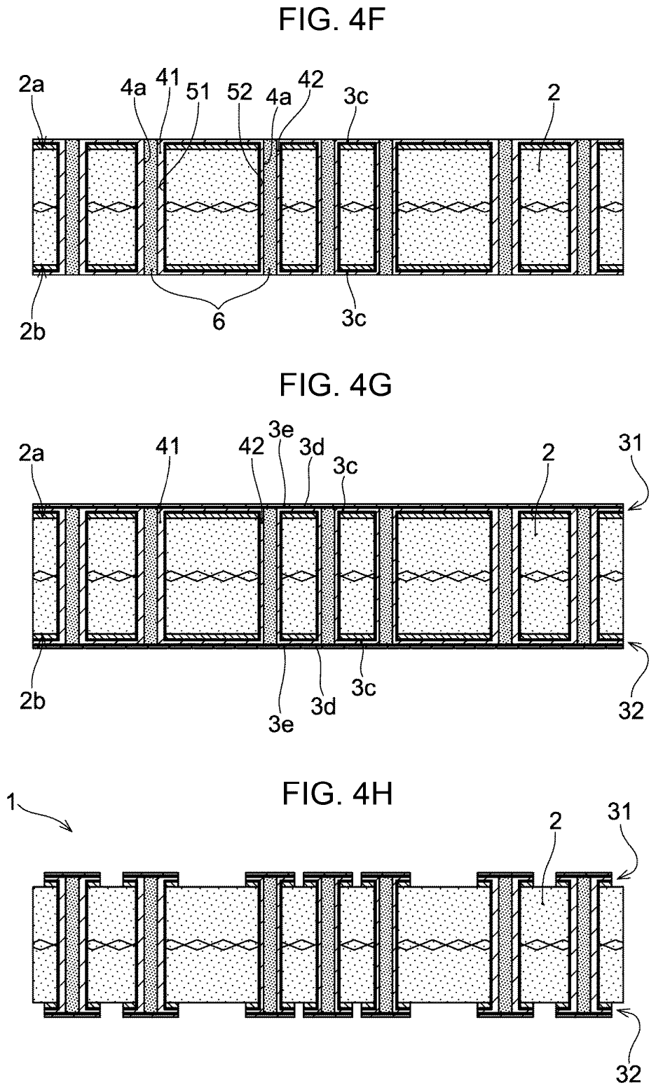

Next, an example of a method for manufacturing the wiring substrate of the embodiment is described with reference to FIGS. 4A-4H, using a case where the wiring substrate 1 of FIG. 1 is manufactured as an example.

As illustrated in FIG. 4A, a double-sided copper-clad laminated plate 10 including an insulating layer, which is to become the insulating layer 2 of the wiring substrate 1, and a copper foil (3a) laminated on both sides of the insulating layer is prepared, and the multiple through holes 5 are formed. The insulating layer of the double-sided copper-clad laminated plate 10 is formed, for example, using an insulating resin such as epoxy resin, and contains a reinforcing material 21 formed of a glass fiber or the like.

The multiple through holes 5 are formed at predetermined positions such that two regions (the first region (A1) and the second region (A2)) with mutually different densities of the through holes 5 are created, the predetermined positions being where the multiple interlayer conductors 4 (see FIG. 1) are to be formed. In the example of FIG. 4A, the second region (A2) having a higher density of the through holes 5 than that of the first region (A1) is created. The first through holes 51 are formed in the first region (A1), and the second through holes 52 are formed in the second region (A2) at a density higher than that of the first through holes 51 in the first region (A1).

In manufacturing the wiring substrate of the present embodiment, as illustrated in FIG. 4A, the first through holes 51 are formed to each have an inner diameter larger than that of each of the second through holes 52. The first through holes 51 and the second through holes 52 are formed, for example, by drilling, and a drill with a larger diameter than the one used for forming the second through holes 52 is used to form the first through holes 51.

As illustrated in FIG. 4B, a metal film (3b) formed of, for example, copper is formed on the entire inner walls of the insulating layer 2 surrounding the first through holes 51 or the second through holes 52 and on the entire surface of the copper foil (3a). The metal film (3b) is formed, for example, by sputtering or electroless plating. A part of the metal film (3b) forms the lower-layer film (40a) (see FIGS. 3A and 3B) of each of the first and second interlayer conductors (41, 42) and the second layer (30b) (see FIGS. 3A and 3B) of each of the conductor layers (31, 32) (see FIG. 1).

Then, as illustrated in FIG. 4C, a metal film (3c) formed of, for example, copper is formed on the entire surface of the metal film (3b). That is, the metal film (3c) is formed on the entire surface of the metal film (3b) in the first through holes 51 or the second through holes 52 and on the entire surface of the metal film (3b) on the copper foil (3a). The multiple first interlayer conductors 41, each having a tubular shape with a hollow part (4a) and composed of a part of the metal film (3b) and a part of the metal film (3c), are formed in the first through holes 51. Similarly, the second interlayer conductors 42, which each have a similar structure to that of the first interlayer conductors 41, are formed in the second through holes 52. A part of the metal film (3c) forms the upper-layer film (40b) of each of the first interlayer conductors 41 and the second interlayer conductors 42 (see FIGS. 3A and 3B). Another part of the metal film (3c) forms the third layer (30c) (see FIGS. 3A, and 3B) of each of the conductor layers (31, 32) (see FIG. 1). The metal film (3c) is formed by electrolytic plating using the metal film (3b) as a power feeding layer.

FIGS. 4D and 4E respectively illustrate enlarged views of a portion (IVD) and a portion (IVE) of FIG. 4C. That is, FIG. 4D illustrates an enlarged view of a first interlayer conductor 41 and its surroundings near the first surface (2a) of insulating layer 2, and FIG. 4E illustrates an enlarged view of a second interlayer conductor 42 and its surroundings near the first surface (2a) of insulating layer 2. As illustrated in FIGS. 4D and 4E, the metal film (3c) is formed such that the thickness (T1) of the first interlayer conductor 41 is larger than the thickness (T2) of the second interlayer conductor 42. Since the arrangement density of the first through holes 51 is smaller than the arrangement density of the second through holes 52, a difference in current density during electrolytic plating between the first region (A1) and the second region (A2) (see FIG. 4A) can be easily created. Therefore, a metal film (3c), of which a thickness in the first through holes 51 is larger than a thickness in the second through holes 52 as illustrated in FIGS. 4D and 4E, can be easily formed.

As illustrated in FIG. 4F, the hollow part (4a) of each of the first interlayer conductors 41 and the second interlayer conductors 42 is filled with the filling body 6. For example, a resin such as an epoxy resin is injected into the hollow part (4a) of each of the interlayer conductors from either one or both of the first surface (2a) side and the second surface (2b) side of the insulating layer 2. Although the thickness of each of the first interlayer conductors 41 is larger than the thickness of each of the second interlayer conductors 42, the inner diameter of each of the first through holes 51 is larger than the inner diameter of each of the second through holes 52. Therefore, the hollow part (4a) of each of the first interlayer conductors 41 and second interlayer conductors 42 is easily and sufficiently filled with the filling body 6. The resin injected into each hollow part (4a) is solidified by heating or the like when necessary. Optionally, end surfaces of the filling body 6 on the first surface (2a) side and the second surface (2b) side are polished using any method such as chemical mechanical polishing. By the polishing, the metal film (3c) on the first surface (2a) and the second surface (2b) of the insulating layer 2 may also be polished. As a result, surface unevenness of the metal film (3c) may be reduced or substantially eliminated.

As illustrated in FIG. 4G, a metal film (3d) formed of, for example, copper or the like is formed on portions of the metal film (3c) on the first surface (2a) and second surface (2b) of the insulating layer 2 and on both end surfaces of the filling body 6. The metal film (3d) is formed, for example, by electroless plating or sputtering. Further, a metal film (3e) formed of, for example, copper or the like is formed on the metal film (3d) by electrolytic plating using the metal film (3d) as a power feeding layer. A so-called cap plating for the first interlayer conductors 41 and second interlayer conductors 42 is formed by the metal film (3d) and the metal film (3e). As a result of the formation of the metal films (3d, 3e), the conductor layer 31 and the conductor layer 32 each having a five-layer structure are formed. The conductor layer 31 is formed on the first surface (2a) of the insulating layer 2, and the conductor layer 32 is formed on the second surface (2b) of the insulating layer 2. A part of the metal film (3d) forms the fourth layer (30d) (see FIGS. 3A and 3B) of each of the conductor layers (31, 32), and a part of the metal film (3e) forms the fifth layer (30e) (see FIGS. 3A and 3B) of each of the conductor layers (31, 32).

As illustrated in FIG. 4H, the conductor layers (31, 32) are each patterned to include desired conductor patterns. For example, etching masks each having appropriate openings are respectively provided on the conductor layers (31, 32), and unwanted portions of the conductor layers (31, 32) are removed by wet etching or dry etching. As a result, the wiring substrate 1 illustrated in FIG. 1 is completed.

The wiring substrate of the embodiment is not limited to those having the structures illustrated in the drawings and those having the structures, shapes, and materials exemplified herein. As described above, the wiring substrate of the embodiment can include any number of conductor layers and insulating layers in addition to the insulating layer 2 and the conductor layers (31, 32) in the example of FIG. 1. It is also possible that the wiring substrate of the embodiment does not include a filling body such as the filling body 6. However, the wiring substrate of the embodiment is more suitable for a structure that includes a filling body that fills the hollow part of each of the multiple interlayer conductors. It is also possible that the wiring substrate of the embodiment has a component mounting region in the first region instead in the second region, or it has a component mounting region that overlaps both the first region and the second region.

Japanese Patent Application Laid-Open Publication No. 2023-20516 describes a method for manufacturing a printed wiring board having a high-density region and a low-density region of through holes formed in an insulating layer. After an electrolytic plating film is formed on both sides of a double-sided copper-clad laminated plate and in the through holes, the electrolytic plating film formed in the low-density region is reduced in thickness by etching while the high-density region is masked. After that, hollow spaces of the through holes are filled with a filling material.

In the method for manufacturing a printed wiring board described in Japanese Patent Application Laid-Open Publication No. 2023-20516, depending on conditions of electrolytic plating and etching, unfilled portions may occur in the hollow spaces in the through holes. For example, it may be difficult to properly fill the hollow spaces in the through holes in both the high-density region and the low-density region. When the hollow spaces are not properly filled and unfilled portions remain, bulging or conductor peeling or the like may occur, potentially hindering improvement in quality of the printed wiring board.

A wiring substrate according to an embodiment of the present invention includes: an insulating layer that has multiple through holes; two conductor layers that oppose each other via the insulating layer; and multiple interlayer conductors that are respectively formed tubular in shape in the multiple through holes and connect the two conductor layers together. The wiring substrate has a first region in which some of the multiple interlayer conductors are formed, and a second region in which some of the multiple interlayer conductors are formed at a higher density than the first region. The multiple through holes include first through holes that are formed in the first region, and second through holes that are formed in the second region at a higher density than a density of the first through holes in the first region. A thickness of each of first interlayer conductors formed in the first through holes among the multiple interlayer conductors is larger than a thickness of each of second interlayer conductors formed in the second through holes among the multiple interlayer conductors. An inner diameter of each of the first through holes is larger than an inner diameter of each of the second through holes.

According to an embodiment of the present invention, it is thought that, in each of the regions with different arrangement densities of the interlayer conductors that connect the conductor layers, interiors of the interlayer conductors are appropriately filled. Therefore, it may be possible that the wiring substrate is improved in quality.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
an insulating layer having a plurality of through holes;
a first conductor layer formed on a first surface of the insulating layer;
a second conductor layer formed on a second surface of the insulating layer on an opposite side with respect to the first surface of the insulating layer;
a plurality of interlayer conductors formed in the plurality of through holes of the insulating layer respectively such that the plurality of interlayer conductors is connecting the first and second conductor layers and includes a plurality of first interlayer conductors formed in a first region of the insulating layer and a plurality of second interlayer conductors formed in a second region of the insulating layer at a density that is higher than a density of the plurality of first interlayer conductors formed in the first region,
wherein the plurality of interlayer conductors is formed such that a thickness of each of the first interlayer conductors is larger than a thickness of each of the second interlayer conductors, and the insulating layer is formed such that the plurality of through holes includes a plurality of first through holes having the plurality of first interlayer conductors formed therein and a plurality of second through holes having the plurality of second interlayer conductors formed therein and that an inner diameter of each of the first through holes is larger than an inner diameter of each of the second through holes.

2. The wiring substrate according to claim 1, wherein the plurality of interlayer conductors is formed such that an inner diameter of each of the first interlayer conductors is substantially equal to an inner diameter of each of the second interlayer conductors.

3. The wiring substrate according to claim 1, wherein the insulating layer is formed such that a difference between the inner diameter of each of the first through holes and the inner diameter of each of the second through holes is substantially twice a difference between the thickness of each of the first interlayer conductors and the thickness of each of the second interlayer conductors.

4. The wiring substrate according to claim 1, wherein the insulating layer is formed such that the inner diameter of each of the first through holes is in a range of 160 μm to 220 μm and that the inner diameter of each of the second through holes is in a range of 150 μm to 200 μm.

5. The wiring substrate according to claim 1, wherein the insulating layer is formed such that a density of the first through holes in the first region is in a range of 0.6 holes/mm² to 1.2 holes/mm² and that a density of the second through holes in the second region is in a range of 6 holes/mm² to 10 holes/mm².

6. The wiring substrate according to claim 1, wherein the insulating layer has a thickness in a range of 1.0 mm to 2.0 mm.

7. The wiring substrate according to claim 1, wherein the plurality of interlayer conductors is formed such that each of the interlayer conductors has a hollow part and includes resin filling the hollow part.

8. The wiring substrate according to claim 1, wherein the insulating layer has a component mounting region formed such that the second region is overlapping with the component mounting region and that the first region is surrounding the second region.

9. The wiring substrate according to claim 2, wherein the insulating layer is formed such that a difference between the inner diameter of each of the first through holes and the inner diameter of each of the second through holes is substantially twice a difference between the thickness of each of the first interlayer conductors and the thickness of each of the second interlayer conductors.

10. The wiring substrate according to claim 2, wherein the insulating layer is formed such that the inner diameter of each of the first through holes is in a range of 160 μm to 220 μm and that the inner diameter of each of the second through holes is in a range of 150 μm to 200 μm.

11. The wiring substrate according to claim 2, wherein the insulating layer is formed such that a density of the first through holes in the first region is in a range of 0.6 holes/mm² to 1.2 holes/mm² and that a density of the second through holes in the second region is in a range of 6 holes/mm² to 10 holes/mm².

12. The wiring substrate according to claim 2, wherein the insulating layer has a thickness in a range of 1.0 mm to 2.0 mm.

13. The wiring substrate according to claim 2, wherein the plurality of interlayer conductors is formed such that each of the interlayer conductors has a hollow part and includes resin filling the hollow part.

14. The wiring substrate according to claim 2, wherein the insulating layer has a component mounting region formed such that the second region is overlapping with the component mounting region and that the first region is surrounding the second region.

15. The wiring substrate according to claim 3, wherein the insulating layer is formed such that the inner diameter of each of the first through holes is in a range of 160 μm to 220 μm and that the inner diameter of each of the second through holes is in a range of 150 μm to 200 μm.

16. The wiring substrate according to claim 3, wherein the insulating layer is formed such that a density of the first through holes in the first region is in a range of 0.6 holes/mm² to 1.2 holes/mm² and that a density of the second through holes in the second region is in a range of 6 holes/mm² to 10 holes/mm².

17. The wiring substrate according to claim 3, wherein the insulating layer has a thickness in a range of 1.0 mm to 2.0 mm.

18. The wiring substrate according to claim 3, wherein the plurality of interlayer conductors is formed such that each of the interlayer conductors has a hollow part and includes resin filling the hollow part.

19. The wiring substrate according to claim 3, wherein the insulating layer has a component mounting region formed such that the second region is overlapping with the component mounting region and that the first region is surrounding the second region.

20. The wiring substrate according to claim 4, wherein the insulating layer is formed such that a density of the first through holes in the first region is in a range of 0.6 holes/mm² to 1.2 holes/mm² and that a density of the second through holes in the second region is in a range of 6 holes/mm² to 10 holes/mm².
